(19) United States
(12) Patent Application Publication
(10) Pub. No.: US 2026/0344414 A1
(43) Pub. Date: Oct. 29, 2026

(54) INTEGRATED CIRCUIT WITH NOISE REDUCING CAPACITOR AND METHOD OF MANUFACTURE

(71) Applicant: Taiwan Semiconductor Manufacturing Company, Ltd., Hsinchu (TW)

(72) Inventors: Ko Chun Liu, Toufen Township (TW); Meng-Hsien Lin, Tainan City (TW); Hsing-Chih Lin, Tainan City (TW); Jen-Cheng Liu, Hsin-Chu City (TW); Dun-Nian Yaung, Taipei City (TW)

(21) Appl. No.: 19/732,702

(22) Filed: Jul. 7, 2026

Related U.S. Application Data
(62) Division of application No. 18/401,752, filed on Jan. 2, 2024.
(60) Provisional application No. 63/611,845, filed on Dec. 19, 2023.

(51) Int. Cl. H10W 20/40; H10D 1/00; H10D 1/68; H10W 20/00; H10W 20/42

(52) U.S. Cl. CPC H10W 20/496; H10D 1/042; H10D 1/716; H10W 20/056; H10W 20/083; H10W 20/42

(57) ABSTRACT

A capacitor is connected between two vias that pass through a passivation stack to couple power supply contacts to a metal interconnect structure. By providing the capacitor with sufficiently high capacitance and sufficiently low equivalent series resistance, it can effectively filter noise in the power supply. The capacitor may have a trench capacitor structure as part of a solution for providing sufficiently high capacitance. Placing all or part of the capacitor within the passivation stack allows the capacitor to be implemented without displacing wiring or devices in the metal interconnect structure.

### REFERENCE TO RELATED APPLICATIONS

This Application is a Divisional of U.S. application Ser. No. 18/401,752, filed on Jan. 2, 2024, which claims the benefit of U.S. Provisional Application No. 63/611,845, filed on Dec. 19, 2023. The contents of the above-referenced Patent Applications are hereby incorporated by reference in their entirety.

### BACKGROUND

The integrated circuit (IC) manufacturing industry has experienced exponential growth over the last few decades. As ICs have evolved, functional density (i.e., the number of interconnected devices per unit chip area) has increased while feature sizes have decreased. Present days ICs may comprise millions or billions of transistors and other devices in complex relationships.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIGS. 1-4 illustrate cross-sectional views of IC devices according to various embodiments of the present disclosure.

FIGS. 5-7 illustrate plan views of IC devices with capacitors according to various embodiments.

FIGS. 8-9 illustrate cross-sectional views of IC devices according to some additional embodiments.

FIGS. 10A and 10B are a pair of plan views illustrating the layouts of first and second capacitor plates in accordance with an embodiment.

FIGS. 11A and 11B are a pair of plan views illustrating the layouts of first and second capacitor plates in accordance with a different embodiment.

FIGS. 12-22 illustrate a series of cross-sectional views showing an IC device undergoing manufacture by a process of the present disclosure.

FIGS. 23-25 illustrate a series of cross-sectional views for a variant of the process illustrated by FIGS. 12-22.

FIG. 26 is a flow chart for a method of manufacturing an IC device in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

Making transistors smaller provides benefits such as higher circuit density and faster switching speeds, but making transistors smaller also makes them more sensitive to voltage fluctuations in a power supply. Small fluctuations can disrupt signal integrity, cause jitter, and otherwise affect the functionality of a circuit.

The present disclosure relates to a structure that mitigates the effects of voltage fluctuations (noise) in the power supply for an integrated circuit. The integrated circuit may be of the type that includes a plurality of metallization layers over a semiconductor substrate and a passivation stack over the uppermost of the metallization layers. Power supply contacts or power rails may be disposed over the passivation stack. A capacitor is connected between two vias that pass through the passivation stack to couple with the power supply contacts or power rails. One of the vias (a V_{DD} via) may carry a supply voltage (V_{DD}). The other via (a V_{SS} via) may be held at a reference voltage (V_{SS}, or ground). In some embodiments, the capacitor is of the metal-insulator-metal (MIM) variety. In some embodiments, the capacitor includes three or more plates. If the capacitor has sufficiently high capacitance and sufficiently low equivalent series resistance, it can effectively filter the noise.

In some embodiments, the capacitor has a 3D structure. The 3D structure provides the capacitor with an effective area that is much greater than its footprint. Increasing the effective area markedly improves the performance of the capacitor in mitigating noise. The 3D structure may include a trench capacitor structure. In some embodiments, the 3D structure includes a plurality of trench capacitor structures. In some embodiments, the plurality of trench capacitor structures are disposed between the two vias. In some embodiments, one or more of the trench capacitor structures is outside the area between the two vias. Utilizing additional area that is outside the area between the two vias allows the capacitance to be increased.

In some embodiments, at least part of the capacitor is within the passivation stack. In some embodiment, the capacitor is entirely within the passivation stack. Placing all or part of the capacitor within the passivation stack allows the capacitor to be implemented without displacing wiring or other structures. The V_{DD} via passes through and connects with a first group of the capacitor plates. The V_{SS} via passes through and connects with a second group of the capacitor plates. In some embodiments, there are a plurality of V_{DD} vias passing through and connecting with the first group of the capacitor plates. In some embodiments, there are a plurality of V_{SS} vias passing through and connecting with the second group of the capacitor plates. In some embodiments, the vias are elongated in a horizontal direction so as to have the form of vertical slabs. A plurality of vias and or elongated vias reduce the equivalent series resistance of the capacitor.

Some aspects of the present disclosure relate to a method of manufacturing an integrated circuit device with a capacitor that mitigates power supply noise. The method begins with a partially manufactured IC device having a metal interconnect structure over a semiconductor substrate. The lower portion of a passivation stack is formed over a top metallization layer of the metal interconnect structure. One or more trenches are etched in the lower portion. A lower plate layer is deposited so as to line the trenches and lie on top of the lower portion of the passivation stack outside the trenches. The lower plate layer is etched from a first via region followed by deposition of a capacitor dielectric layer and an upper plate layer. The upper plate layer is etched from a second via region. Additional capacitor dielectric and plate layers may be deposited and similarly etched to complete the formation of the capacitor. The upper portion of the passivation stack is formed over the capacitor. Holes, which may be trenches, are etched through the passivation layer and through the capacitor plates. The holes include a first hole in the first region and a second hole in the second region. The holes are filled with conductive material to form a first via in the first hole and a second via in the second hole. The first via contacts the upper plate layer and a first wire in top metallization layer. The second via contacts the lower plate layer and a second wire in top metallization layer. Contact pads or power rails may be formed over the passivation layer so as to form connections to the first and second vias.

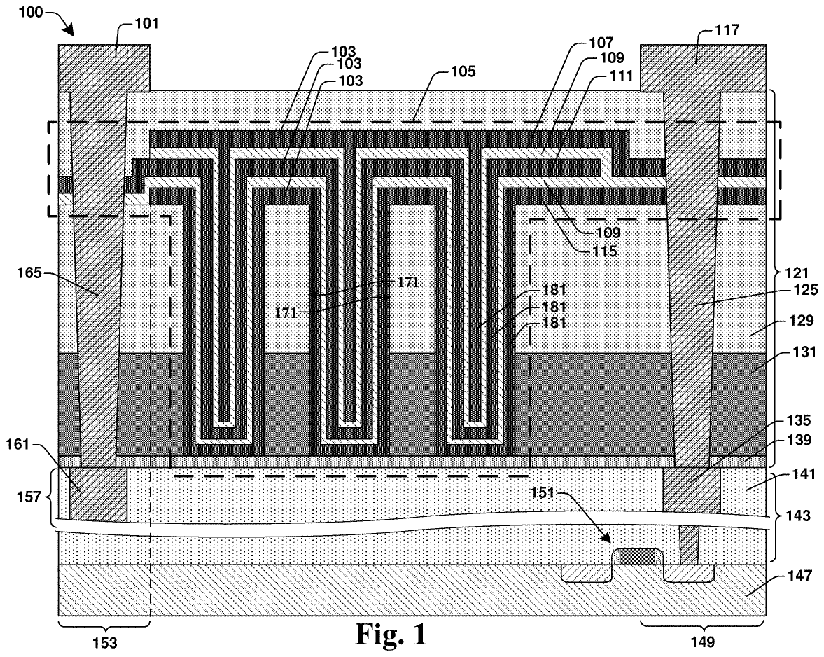

FIG. 1 illustrates an IC device 100 in accordance with some aspects of the present disclosure. The IC device 100 includes a metal interconnect structure 143 over a semiconductor substrate 147. The metal interconnect structure 143 comprises a plurality of metallization layers including a top metallization layer 157, which is uppermost in the metal interconnect structure 143. A passivation stack 121 is disposed over the top metallization layer 157. A first contact pad 101 and a second contact pad 117 are on top of the passivation stack 121. A first via 165 passes through the passivation stack 121 to couple the first contact pad 101 to a first wire 161 in the top metallization layer 157. A second via 125 passes through the passivation stack 121 to couple the second contact pad 117 to a second wire 135 in the top metallization layer 157.

A capacitor 105 is disposed in the passivation stack 121 and is coupled between the first via 165 and the second via 125. The capacitor 105 may include, in order from lowest to highest, a first plate 115, a second plate 111, and a third plate 107. A capacitor dielectric 109 separates the first plate 115 from the second plate 111 and the second plate 111 from the third plate 107. The first via 165 passes through, is surrounded by, and connects with the second plate 111 in a first contact region 153. The first plate 115 and the third plate 107 are absent from the first contact region 153. The second via 125 passes through, is surrounded by, and connects with the first plate 115 and the third plate 107 in a second contact region 149. The second plate 111 is absent from the second contact region 149.

The first contact pad 101 may be a V_{DD} contact pad and the second contact pad 117 may be a V_{SS} contact pad. When a supply voltage is coupled to the first contact pad 101 and a reference voltage is couple to the second contact pad 117, the IC device 100 is powered and becomes operative. The capacitor 105 buffers fluctuations in the supply voltage so that the voltage on the first wire 161 is steadier than the voltage on the first contact pad 101. In some embodiments, the capacitor 105 reduces peak-to-peak voltage variations by 50% or more. In some embodiments, the capacitor 105 reduces peak-to-peak voltage variations by 75% or more.

The capacitor 105 is a 3D MIM capacitor comprising a trench capacitor structure. The trench capacitor structure means that the first plate 115, the second plate 111, and the third plate 107 comprise vertical plates 181 that are within a trench defined by sidewalls 171 of the passivation stack 121. The first plate 115, the second plate 111, and the third plate 107 also comprise horizontal plates 103. The vertical plates 181 allow the capacitor 105 to have an effective area that is greater than its footprint. In some embodiments, the effective area is from about 3 to about 10 times greater than the footprint. In some embodiments, the effective area is from about 10 to about 50 times greater than the footprint. In some embodiments, the capacitor 125 has vertical plates 181 within three or more distinct trenches.

The passivation stack 121 is a dielectric structure that may include an etch stop layer 139, a barrier layer 131, and an oxide layer 129. The etch stop layer 139 may be a material such as silicon nitride (SiN), silicon carbide (SiC), silicon carbonitride (SiCN), silicon oxycarbide (SIOC), silicon oxycarbonitiride (SiOCN), combinations thereof, or the like. The barrier layer 131 may be a material such as silicon nitride (SiN) or the like that provides superior moisture resistance and has greater mechanical strength than silicon dioxide (SiO₂). In some embodiments, the material of the barrier layer 131 is distinct from the material of the etch stop layer 139. In some embodiments, the first plate 115 abuts the etch stop layer 139.

The oxide layer 129 may be silicon dioxide (SiO₂) or the like, which provides good insulation and process compatibility. In some embodiments, the passivation stack 121 has a thickness in the range from about 0.5 μm to about 3 μm. In some embodiments, the passivation stack 121 has a thickness in the range from about 1.9 μm to about 2.2 μm. In some embodiments, the etch stop layer 139 has a thickness in the range from about 5 nm to about 50 nm. In some embodiments, the barrier layer 131 has a thickness of at least about 0.2 μm. In some embodiments, the oxide layer 129 has a thickness of at least about 0.3 μm. The material of the barrier layer 131 may be the same as that of the etch stop layer 139 or that of another etch stop layer such as one found in the metal interconnect structure 143, but the barrier layer 131 is much thicker than any etch stop layer in the IC device 100.

The dielectric layers in the passivation stack 121 are generally distinct from the dielectric layers in the metal interconnect structure 143. The metal interconnect structure 143 includes a low-k dielectric layer 141. The low-k dielectric 141 may be, for example, an organosilicate glasses (OSG) such as carbon-doped silicon dioxide, a fluorinated silica glass (FSG), a porous silicate glass, or the like.

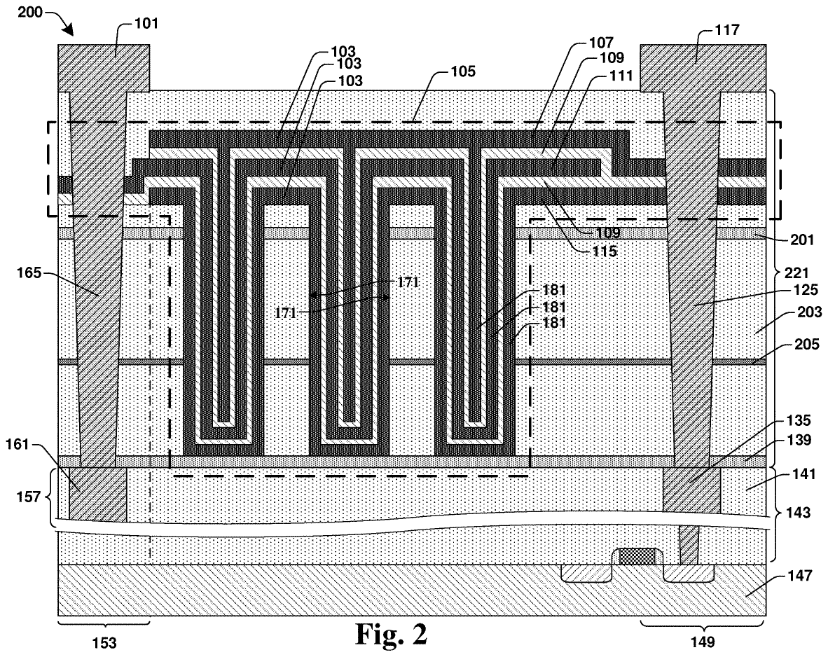

FIG. 2 illustrates an IC device 200 which is like the IC device 100 of FIG. 1 except that the IC device 200 has a passivation stack 221 that has a different structure from the passivation stack 121 of the IC device 100. The passivation stack 221 may have a dielectric structure similar to that of metal interconnect structure 143. The passivation stack 221 includes a low-k dielectric layer 203, a first etch stop layer 205, and a second etch stop layer 201. The low-k dielectric 203 may have the same composition as the low-k dielectric layer 141. The first etch stop layer 205 or the second etch stop layer 201 may have the same composition and thickness as the etch stop layer 139. While the passivation stack 221 may not have the same protective qualities as the passivation stack 121, it has the advantage that it may be formed by a continuation of the process loop used to form the metal interconnect structure 143.

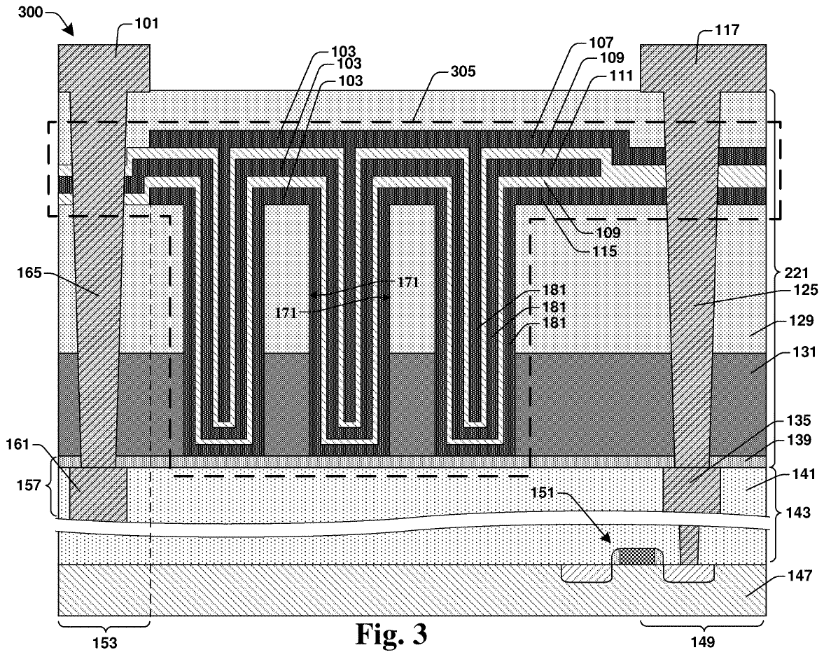

FIG. 3 illustrates an IC device 300 which is like the IC device 100 of FIG. 1 except the IC device 300 has a capacitor 305. The capacitor 305 is like the capacitor 105 of the IC device 100 except for some differences in the structure of the capacitor dielectric 109. In the capacitor 305, the capacitor dielectric 109 extends over the second plate 111 in the first contact region 153 and has a greater thickness between the first plate 115 and the third plate 107 in the second contact region 149. These differences result from a difference in processing. In particular, the IC device 300 is manufactured with etch processes that stop on the capacitor dielectric 109 as will be described in greater detail below. The capacitor 305 has a slightly lower capacitance as compared to the capacitor 105 of FIG. 1, but may have advantages in terms of reliability or ease of manufacture.

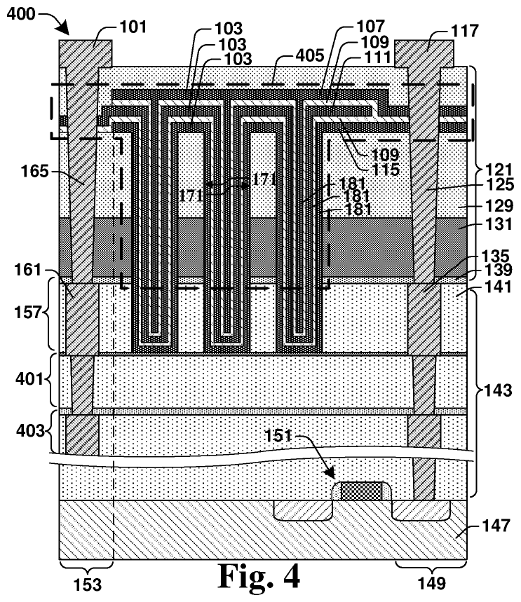

FIG. 4 illustrates an IC device 400 which is like the IC device 100 of FIG. 1 except the IC device 400 has a capacitor 405. The capacitor 405 extends below the passivation stack 121 into the top metallization layer 157. Optionally, the capacitor 405 can extend deeper into the metal interconnect structure 143. In some embodiments, the capacitor 405 extends into the via layer 401 that is between the top metallization layer 157 and the second from top metallization layer 403. In some embodiments, the capacitor 405 extends into the via layer 401. In some embodiments, the capacitor 405 extends into the second from top metallization layer 403. Having the capacitor 405 extend more deeply into the metal interconnect structure 143 causes the capacitor 405 to take up more space, but allows the capacitance to be increased without increasing the capacitor's footprint.

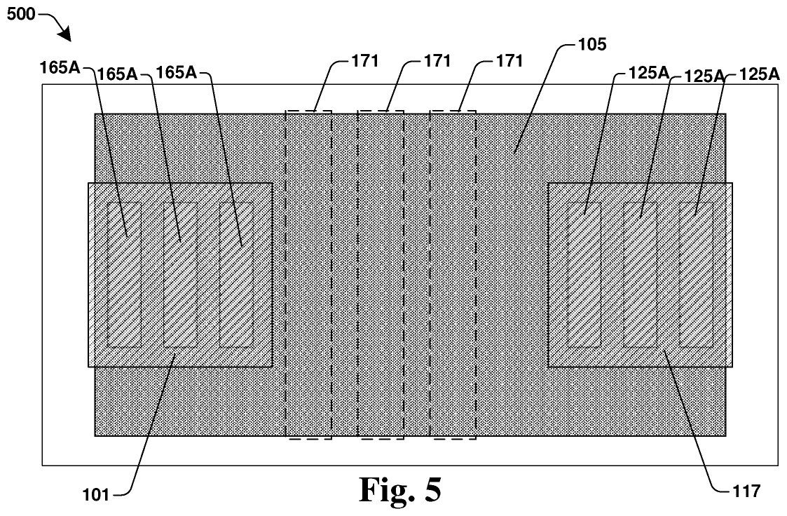

FIG. 5 illustrates a plan view 500, which is a plan view that corresponds to the IC device 100 of FIG. 1 in some embodiments. In the plan view 500 there are three first vias 165A and three second vias 125A. The first vias 165 and the second vias 125 are elongated to form vertical slabs. In some embodiment, the lengths of the first vias 165 and the second vias 125 are two or more times their widths. In some embodiment, the lengths of the first vias 165 and the second vias 125 are four or more times their widths. Having multiple vias, and having vias elongated into slabs, reduces the equivalent series resistance of the capacitor 105.

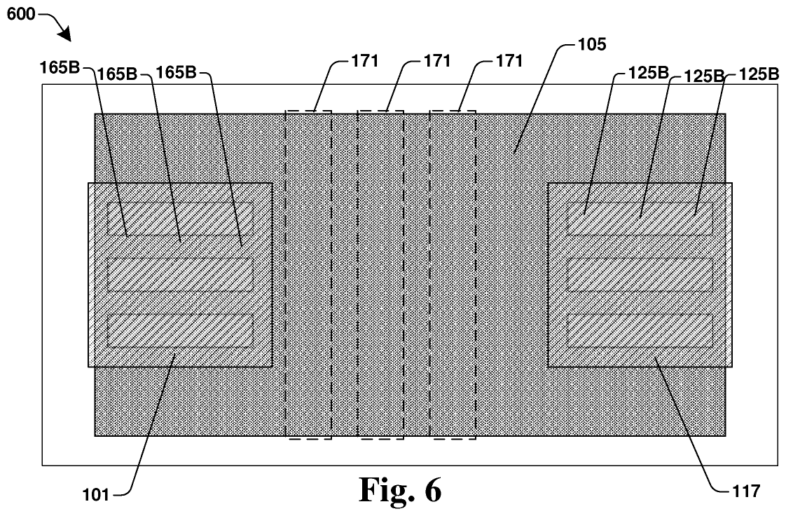

FIG. 6 illustrates a plan view 600, which is another plan view that may correspond to the IC device 100 of FIG. 1 in some embodiments. In the plan view 600 there are three first vias 165B and three second vias 125B. The first vias 165B and the second vias 125B are like the first vias 165A and the second vias 125A of the plan view 500 except that whereas the first vias 165A and the second vias 125A are elongated in the same direction as the trenches defined by the sidewalls 171, the first vias 165B and the second vias 125B are elongated perpendicular to the trenches defined by the sidewalls 171.

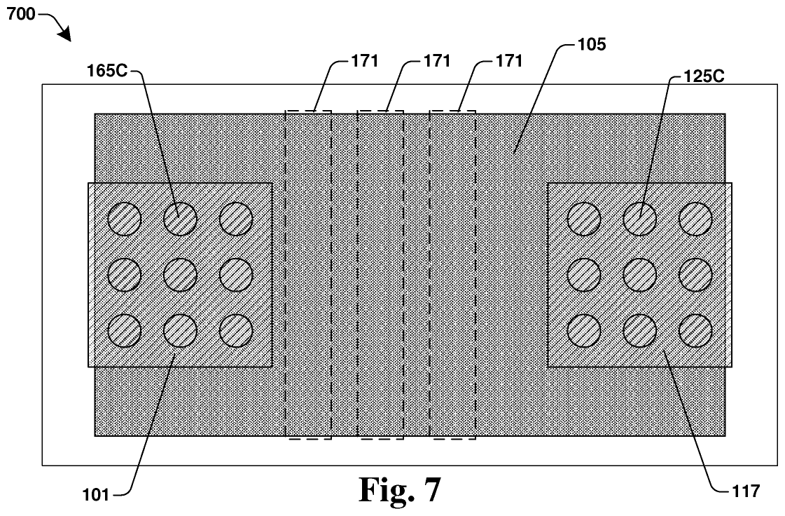

FIG. 7 illustrates a plan view 700, which is another plan view that may correspond to the IC device 100 of FIG. 1 in some embodiments. In the plan view 700 there are nine first vias 165C and nine second vias 125C. The first vias 165C and the second vias 125C are round or oval and are arranged in arrays. These may be 2×2 arrays, 3×3 arrays as shown, or arrays with some other number of rows and columns. Having a large number of vias provides a similar effect to having elongated vias.

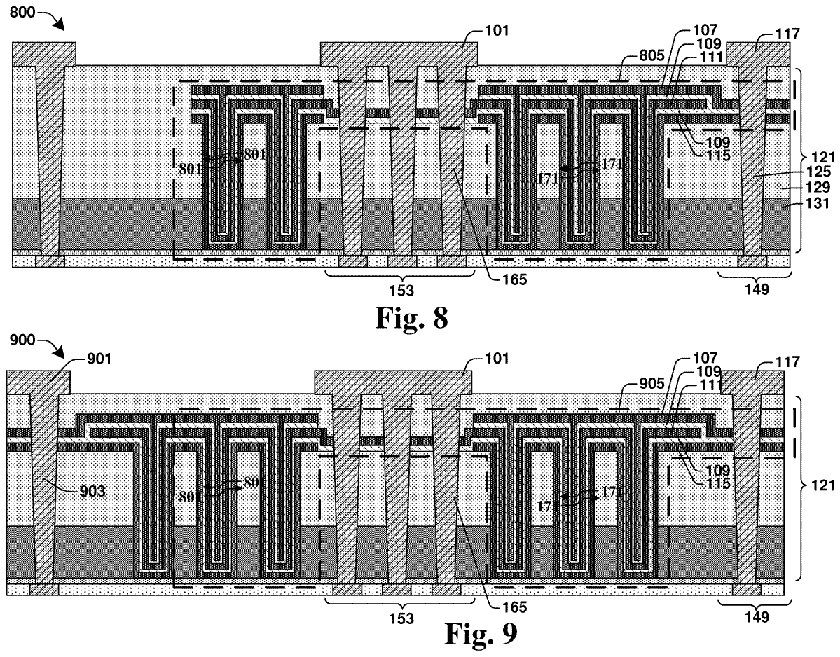

FIG. 8 illustrates a cross-sectional view of an IC device 800 according to another embodiment. The IC device 800 is like the IC device 100 of FIG. 1 except the IC device 800 has a capacitor 805 with an expanded area that includes additional trench structures. The capacitor 805 has trenches structures between sidewalls 171 of the passivation stack 121 in the area between the first via 165 and the second via 125 and additional trench structures between sidewalls 801 of the passivation stack 121 which are on the opposite side of the first via 165 from the second via 125. This embodiment illustrates the concept of using additional area outside the space between the first contact pad 101 and the second contact pad 117 to increase capacitance.

FIG. 9 illustrates a cross-sectional view of an IC device 900 according to another embodiment. The IC device 900 is like the IC device 800 of FIG. 8 except the IC device 900 has a capacitor 905, which is further extended to make connections with one or more third vias 903 coupled to a third contact pad 901. The third contact pad 901 may be connected to the same power supply pole as the second contact pad 117. The third vias 903 connect to the capacitor 905 in parallel with the second vias 125. This embodiment illustrates a further increase in area and connectivity that may be used to improve noise filtering.

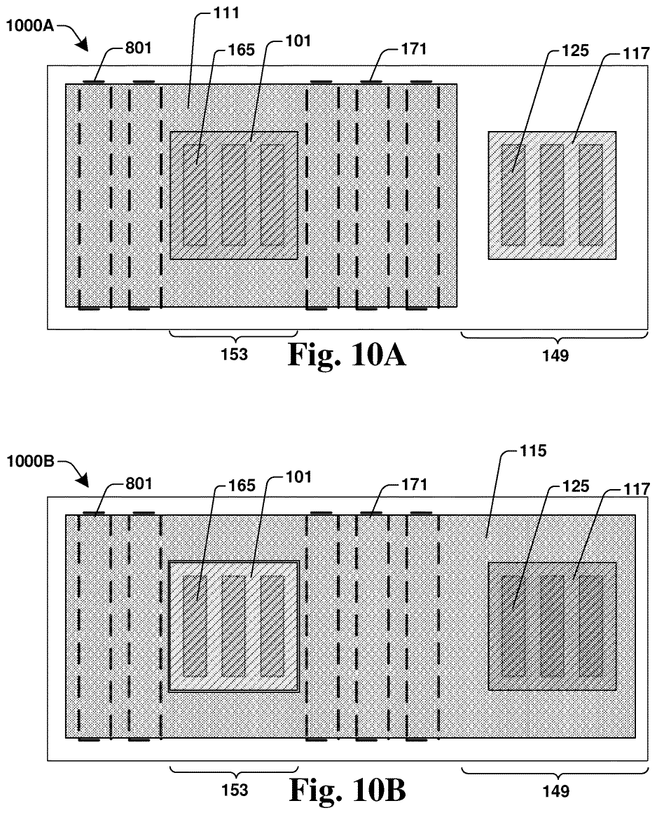

FIGS. 10A and 10B illustrate plan views 1000A and 1000B, which corresponding to the IC device 800 of FIG. 8. The plan view 1000A shows the layout of the second plate 111. As shown by the plan view 1000A, the second plate 111 may stop before the second contact region 149. The plan view 1000B shows the layout of the first plate 115. As shown by the plan view 1000B, the first plate 115 may extend around the first contact region 153 so as to provide continuity between portions of the first plate 115 on one side of the first contact region 153 and portions of the first plate 115 on an opposite side of the first contact region 153. In some embodiments, the first plate 115 surrounds the first contact region 153.

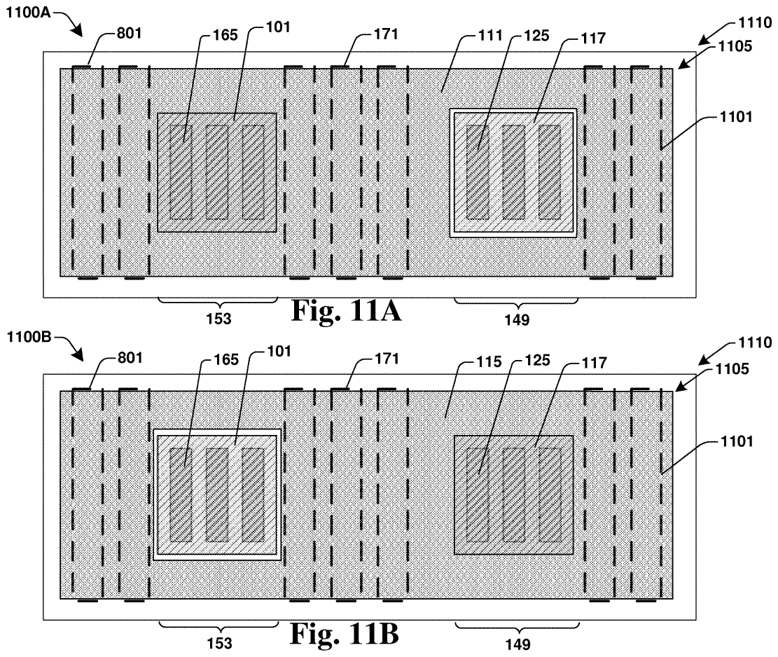

FIGS. 11A and 11B illustrate plan views 1100A and 1100B, which corresponding to an IC device 1110 according to another embodiment. The IC device 1110 is like the IC device 800 of FIG. 8, except that the IC device 1110 has a capacitor 1105 that include additional trench structures between sidewalls 1101 of the passivation stack 121. The sidewalls 1101 are on an opposite side of the second contact region 149 from the first contact region 153. The capacitor 1105 has a first plate 115 that extends through the second contact region 149 and a second plate 111 that extends around the second contact region 149. This embodiment illustrates another possible expansion of the capacitor area. The capacitor area may be expanded even further by extending up to and around contact regions associated with adjacent contact pads (not shown).

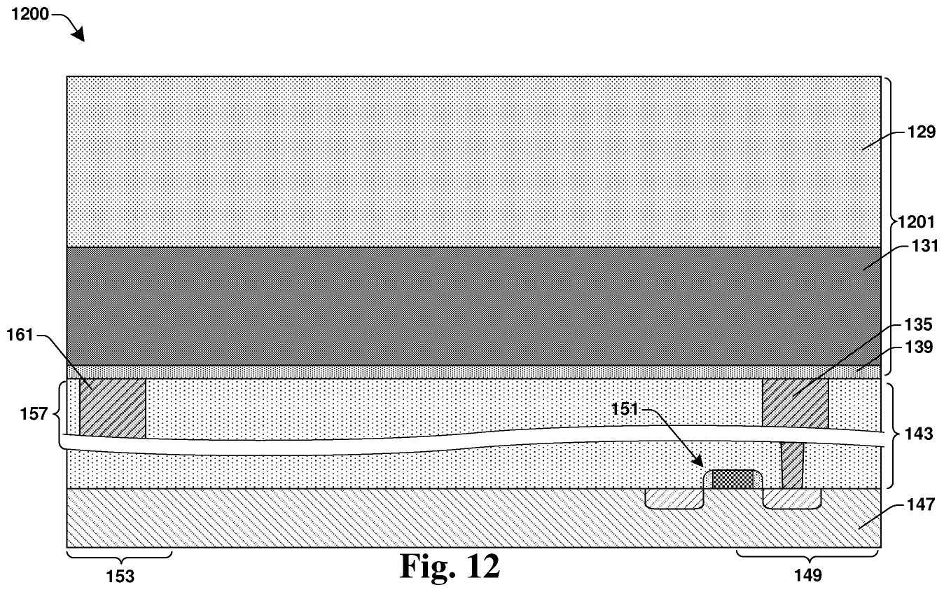

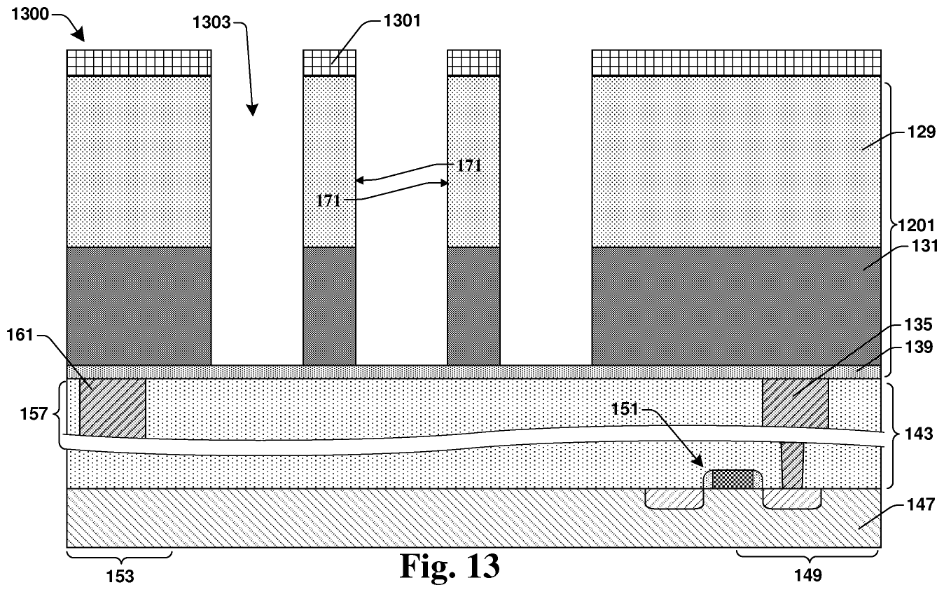

FIGS. 12-22 provide a series of cross-sectional views 600-4400 that illustrate an integrated circuit device according to the present disclosure at various stages of manufacture according to a process of the present disclosure. Although FIGS. 12-22 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 12-22 are described in relation to a series of acts, it will be appreciated that the structures shown in FIGS. 12-22 are not limited to a method of manufacture but rather may stand alone as structures separate from the method.

As shown by the cross-sectional view 1200 of FIG. 12, the process may begin with forming the lower portion of the passivation stack 1201 on a partially manufactured integrated circuit device that includes the semiconductor substrate 147 and the metal interconnect structure 143. The metal interconnect structure 143 includes a plurality of wires, such as the first wire 161 and the second wire 135, and a plurality of vias respectively grouped into a plurality of metallization layers and a plurality of via layers that are alternatingly stacked. The top metallization layer 157 is the uppermost of the metallization layers. The lower portion of the passivation stack 1201 include the etch stop layer 139, the barrier layer 131, and a portion of the oxide layer 129. The lower portion of the passivation stack 1201 may have additional or different layers such as the low-k dielectric layer 203, the etch stop layer 205, and the etch stop layer 201 as shown in FIG. 2.

The semiconductor substrate 147 may be a bulk semiconductor substrate or a semiconductor on insulator (SOI) substrate. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. Various semiconductor devices such as a transistor 151 may be formed on the semiconductor substrate 147. The transistor 151 may be in a circuit that becomes operational when connected to a power supply. The wires and vias may be, for example, copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, or the like.

As shown by the cross-sectional view 1300 of FIG. 13, a mask 1301 may be formed and used to etch trenches 1303 in the passivation stack 1201. The mask 1301 and other masks used in this process may be or comprise a photoresist, a hard mask, or the like. The mask 1301 and other masks used in this process may be patterned by photolithography, ion beam lithography, the like, or some other suitable process. The trenches 1303 have sidewalls 171 provided by the passivation stack 1201. The etch process may be a dry etch such as a plasma etch or the like. In some embodiments, the etching stops on the etch stop layer 139 or some other etch stop layer which provides the bottoms of the trenches 1303. Providing the etch stop layer 139 with a distinct composition from the barrier layer 131 allows the etch stop layer 139 to function as an etch stop. After etching, the mask 1301 may be stripped.

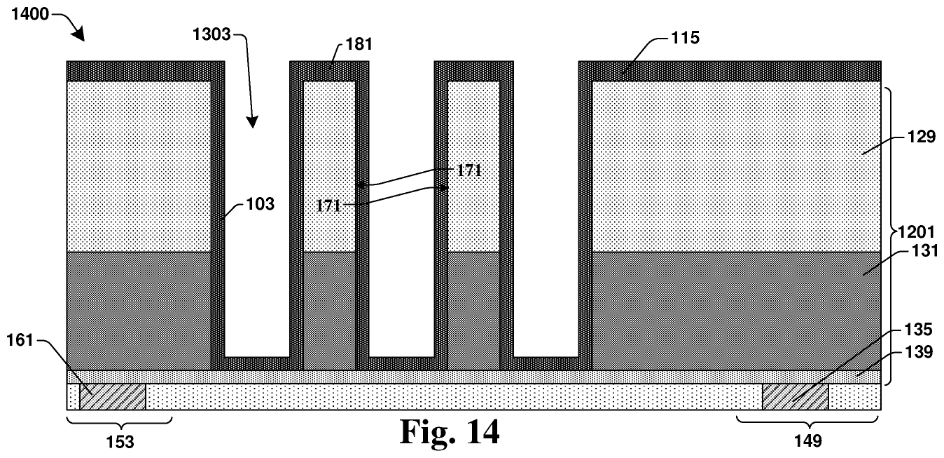

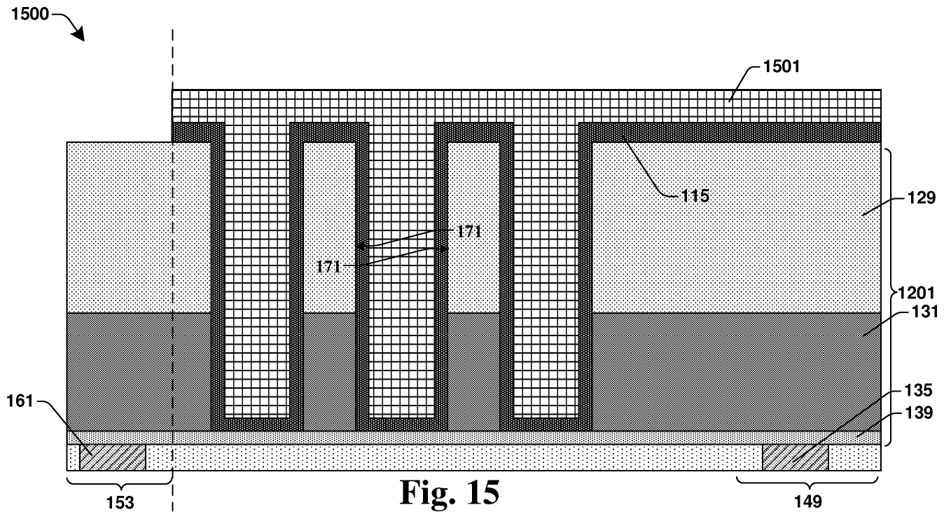

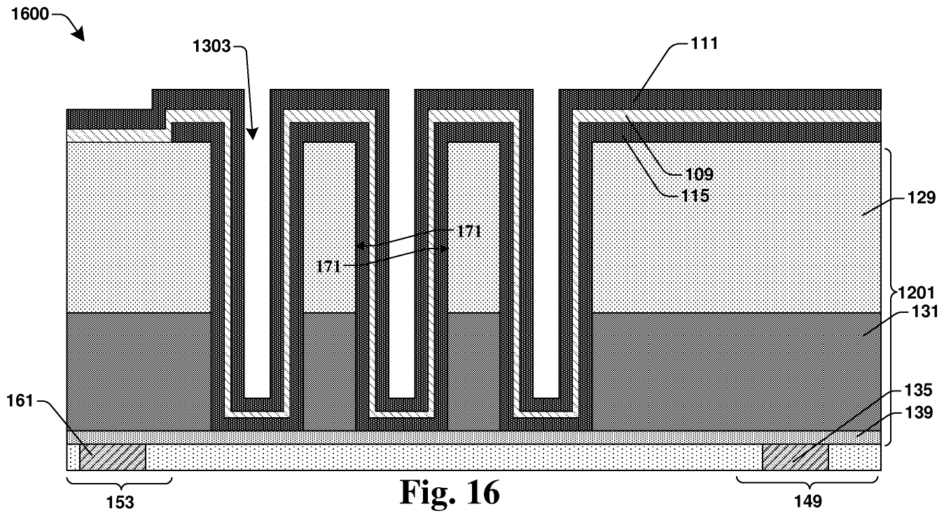

As shown by the cross-sectional view 1400 of FIG. 14, an electrode metal layer is deposited so as to form the first plate 115 over the structure illustrated by the cross-sectional view 1300 of FIG. 13. The electrode metal layer depositing in the trenches 1303 lines the sidewalls 171 so as to form vertical plates 181. The electrode metal layer depositing over the lower portion of the passivation stack 1201 form horizontal plates 103.

An electrode metal layer may be, for example, titanium nitride (TiN), tungsten (W), titanium (Ti), tantalum (Ta), titanium nitride (TaN), copper (Cu), silver (Ag), aluminum (Al), nickel (Ni), a conductive alloy thereof, or the like. In some embodiments, the electrode metal layer is titanium nitride (TiN) or the like. Using titanium nitride (TiN) for the electrode metal layer contributes to exceptionally low equivalent series resistance. In some embodiments, the electrode metal layer is deposited to a thickness in the range from about 1 nm to about 20 nm. In some embodiments, the electrode metal layer is deposited to a thickness in the range from about 20 nm to about 50 nm. Thinner electrode metal layer depositions allow more plates to be deposited in the trenches 1303 and can provide higher capacitance. Thicker electrode metal layer depositions can reduce equivalent series resistance. The electrode metal layer may be deposited by physical vapor deposition (PVD), chemical vapor deposition (CVD), atomic layer deposition (ALD), electroplating, electroless plating, the like, or any other suitable process.

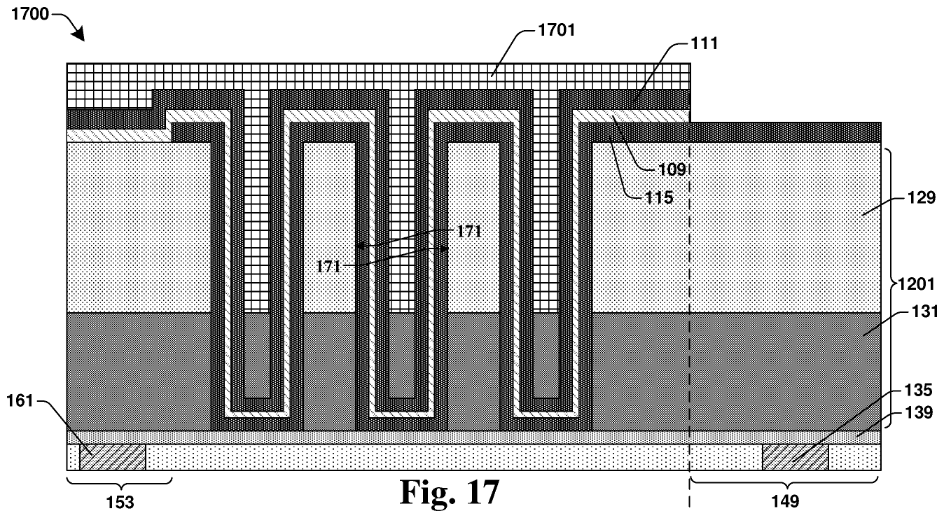

As shown by the cross-sectional view 1500 of FIG. 15, a mask 1501 is formed and used to etch the first plate 115 from the first contact region 153. The etch process may be a dry etch, such as a plasma etch, the like, or some other suitable etch process. After etching, the mask 1501 is stripped.

As shown by the cross-sectional view 1600 of FIG. 16, a layer of the capacitor dielectric 109 and a second electrode metal layer are deposited over the structure illustrated by the cross-sectional view 1500 of FIG. 15. The second electrode metal layer provides the second plate 111 and may have the same composition as the first plate 115 (or a different composition). The second electrode metal layer may be deposited by the same process as the first electrode metal layer (or a different process), and may be deposited to the same thickness (or a different thickness). The capacitor dielectric 109 may be any suitable dielectric. In some embodiments, the capacitor dielectric 109 is a high-k dielectric. Examples of high-k dielectrics include, without limitation, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂—Al₂O₃), zirconium oxide (ZrO₂), tantalum oxide (Ta₂O₅), aluminum oxide (Al₂O₃), yttrium oxide(Y₂O₃), lanthanum oxide (La₂O₃), strontium titanium oxide (SrTiO₃), and the like.

The capacitor dielectric 109 may be deposited to any suitable thickness. In some embodiments, the capacitor dielectric 109 is deposited so as to have a thickness in the range from about 5 nm to about 20 nm within the trenches 1303. In some embodiments, the capacitor dielectric 109 has the same thickness outside the trenches 1303. In some embodiments, the capacitor dielectric 109 is deposited so as to have a greater thickness outside the trenches 1303, i.e., on top of the lower portion of the passivation stack 1201. In some embodiments, the thickness is greater by 50% or more. In some embodiments, the thickness is greater by a factor of 2 or more. Providing the capacitor dielectric 109 with a greater thickness on top of the lower portion of the passivation stack 1201 may reduce leakage currents. The capacitor dielectric 109 may be deposited by ALD, CVD, PVD, the like, or any suitable process. ALD, CVD, or PVD may be used to provide the capacitor dielectric 109 with a uniform thickness, with ALD being most effective for that purpose. CVD or PVD may be used to provide the capacitor dielectric 109 with a greater thickness outside the trenches 1303.

As shown by the cross-sectional view 1700 of FIG. 17, a mask 1701 may be formed and used to etch the second plate 111 from the second contact region 149. The etch process may be a dry etch, such as a plasma etch, the like, or some other suitable etch process. The etch may stop on the first plate 115. After etching, the mask 1701 may be stripped.

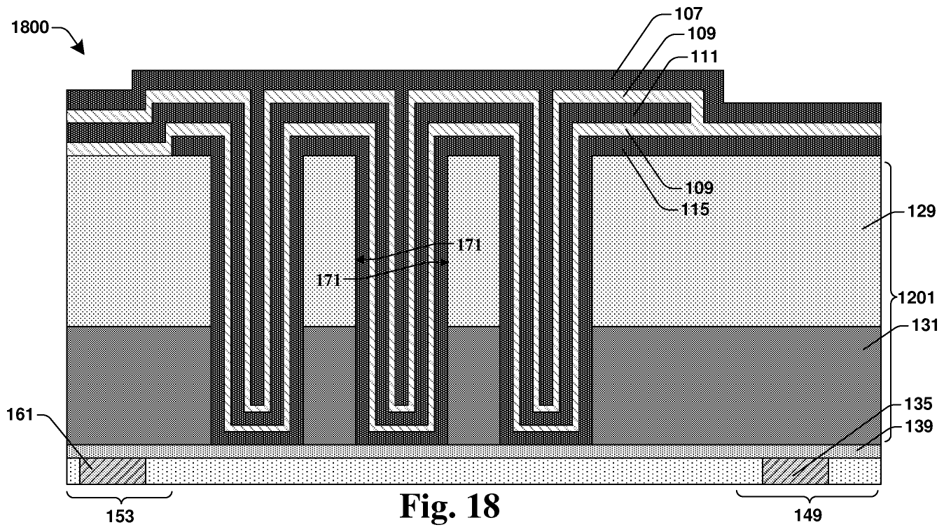

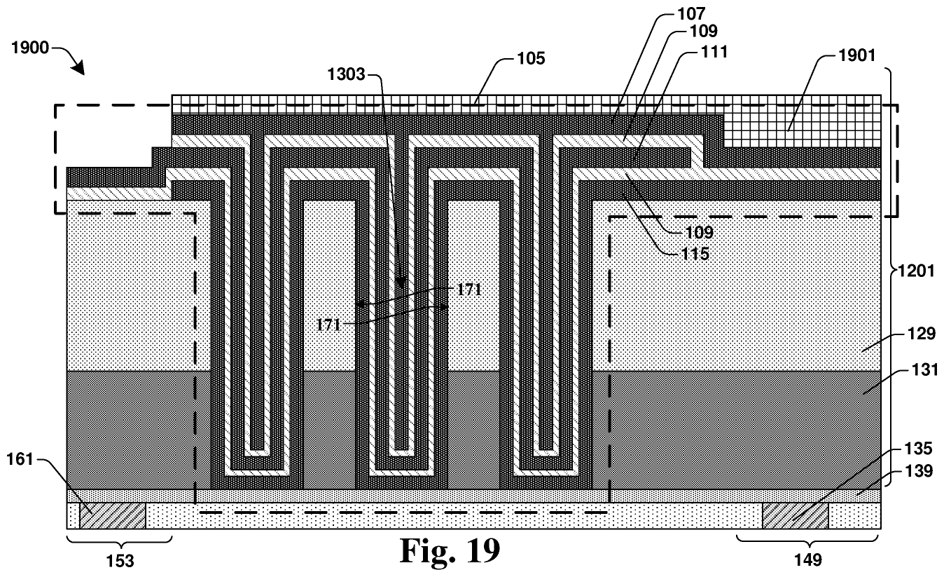

As shown by the cross-sectional view 1800 of FIG. 18, another layer of the capacitor dielectric 109 may be deposited followed by a third electrode metal layer which provides the third plate 107. As shown by the cross-sectional view 1900 of FIG. 19, a mask 1901 may be formed and used to etch the third plate 107 from the first contact region 153. The processes of FIGS. 18 and 19 are optional in that the capacitor 105 may have only two plates. On the other hand, additional capacitor dielectric and electrode metal layers may be deposited and etched to provide more plates up to the point at which the trenches 1303 are filled. In some embodiments, the last electrode metal layer deposition fills the trenches 1303.

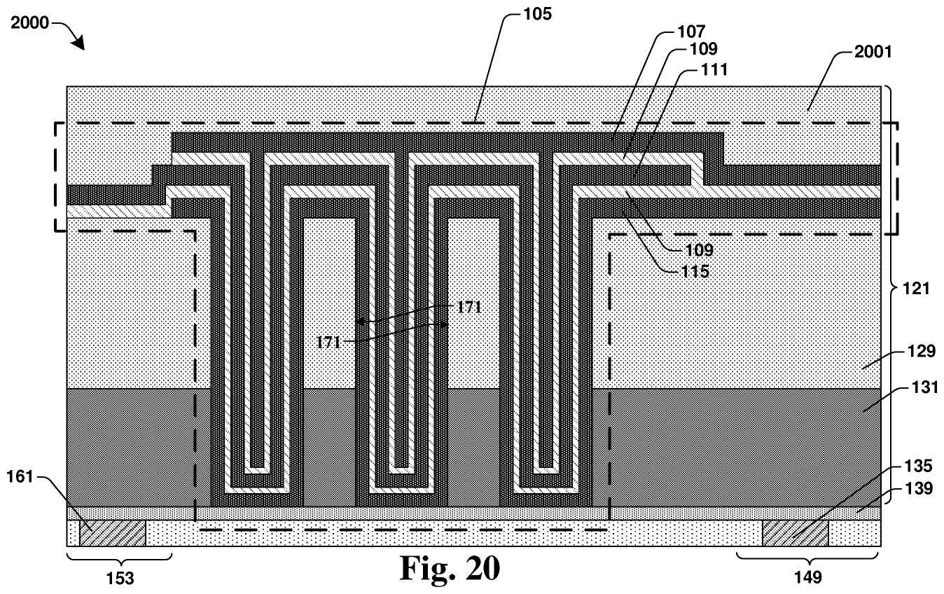

As shown by the cross-sectional view 2000 of FIG. 20, an upper portion 2001 of the passivation stack 121 may be deposited so as to complete the formation of the passivation stack 121. The upper portion 2001 may be more of the oxide layer 129 or may be some other dielectric. In some embodiments, the upper portion 2001 comprises silicon nitride (SiN) or the like, which provides a capping layer.

The upper portion 2001 may be a small fraction of the overall thickness of the passivation stack 121 so that the trenches defined by the sidewalls 171 extend through most of the passivation stack 121. In some embodiments, the upper portion 2001 is about 20% or less the thickness of the passivation stack 121. In some embodiments, the upper portion 2001 is about 10% or less the thickness of the passivation stack 121. In some embodiments, the upper portion 2001 is about 5% or less the thickness of the passivation stack 121.

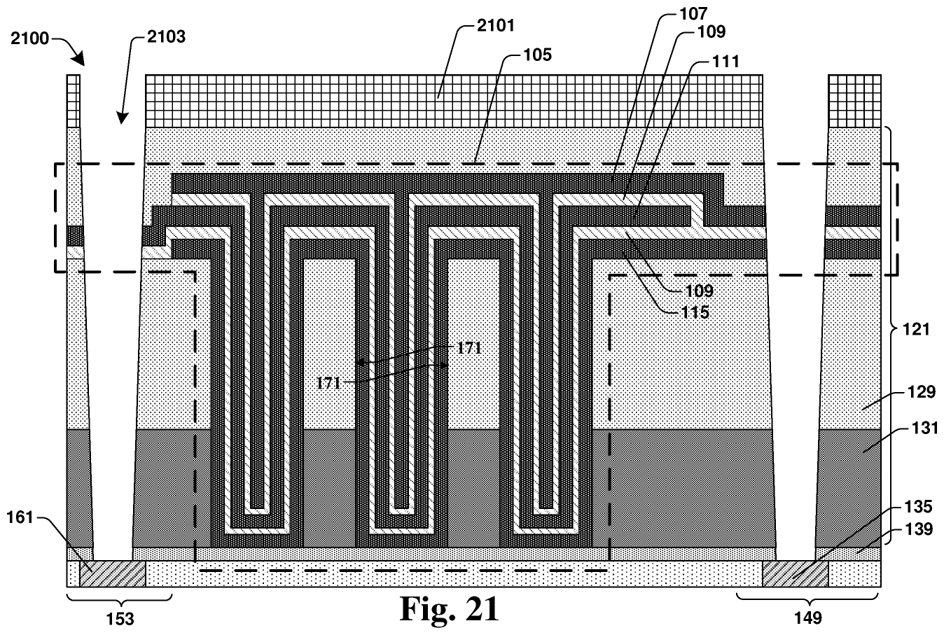

As shown by the cross-sectional view 2100 of FIG. 21, a mask 2101 may be formed and used to etch holes 2103 through the passivation stack 121. The etch process may be one or more stages of dry etching, such as plasma etching, the like, or any other suitable etch process or processes. In some embodiments, the holes 2103 are elongated so that they are trenches. In the first contact region 153, the holes 2103 pass through the second plate 111 and expose the first wire 161. In the second contact region 149, the holes 2103 pass through the first plate 115 and the third plate 107 and expose the second wire 135.

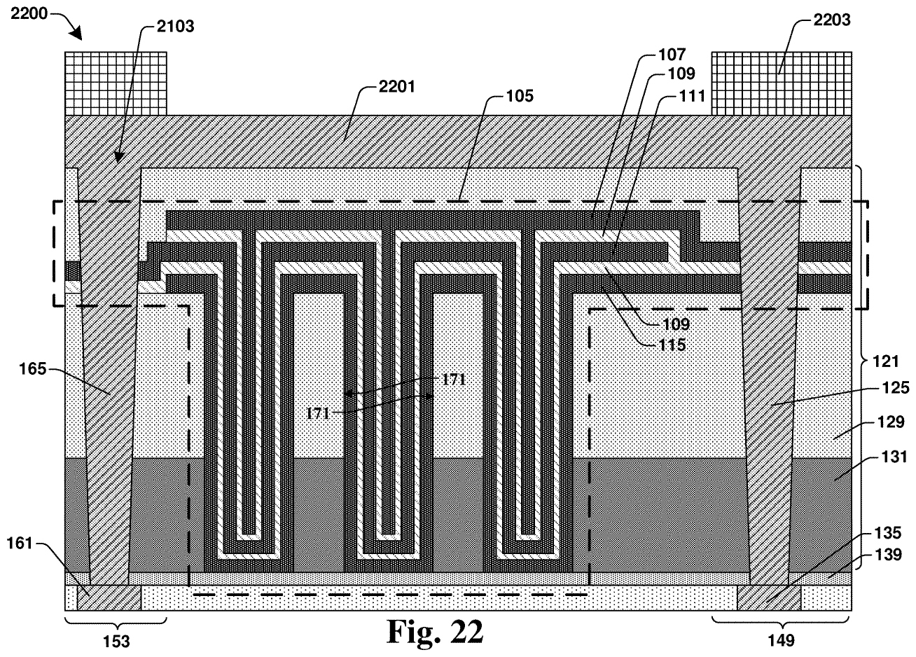

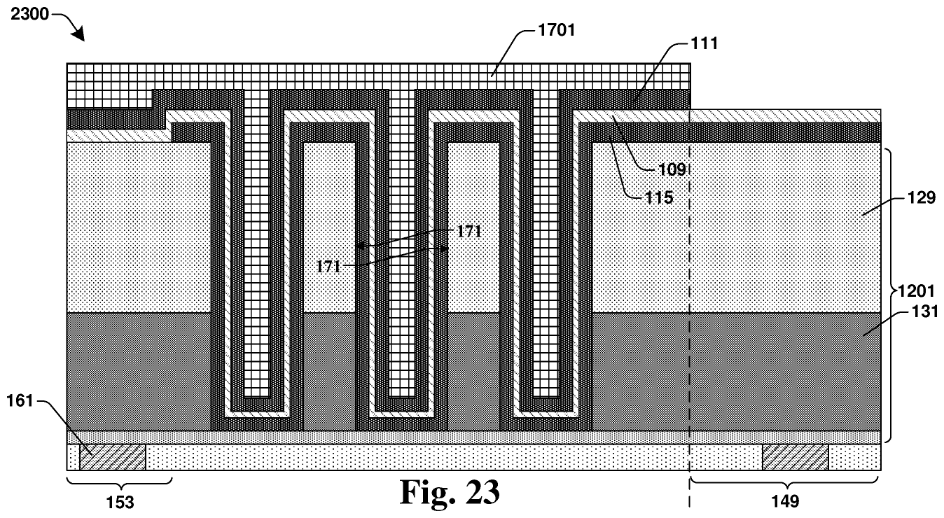

As shown by the cross-sectional view 2200 of FIG. 22, a metal 2201 or other conductive material is deposited so as to fill the holes 2103 and provide the first via 165 and the second via 125. The metal 2201 may be the same as that of the first wire 161 and the second wire 135. In some embodiments the metal 2201 is a distinct metal from the metal of the first wire 161 and the second wire 135. The metal 2201 may be deposited by PVD, CVD, electroplating, electroless plating, the like, or any other suitable process. After deposition, the metal 2201 may be planarized. In some embodiments, planarization leaves a layer of the metal 2201 over the passivation stack 121. A mask 2203 may be formed and used to pattern this metal 2201 to form the first contact pad 101 and the second contact pad 117 as shown in FIG. 1. The metal 2201 over the passivation stack 121 may alternatively be patterned to form power rails.

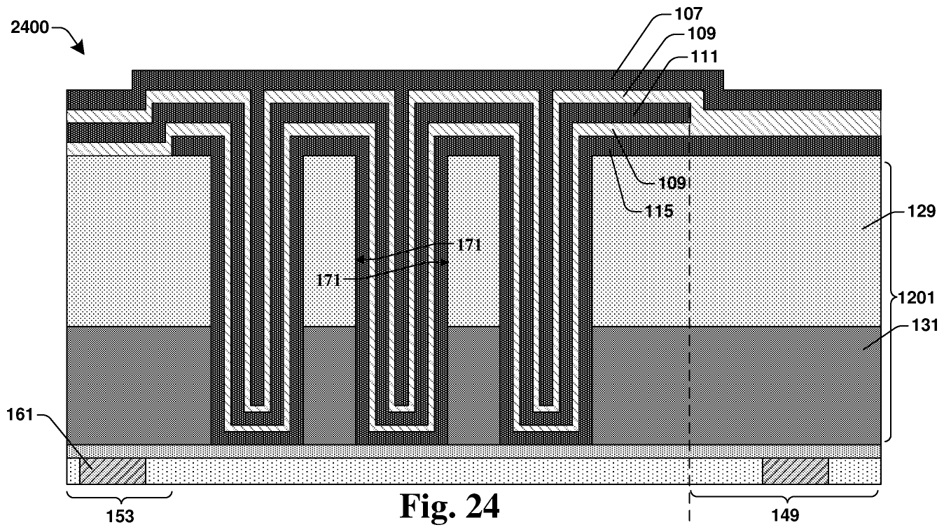

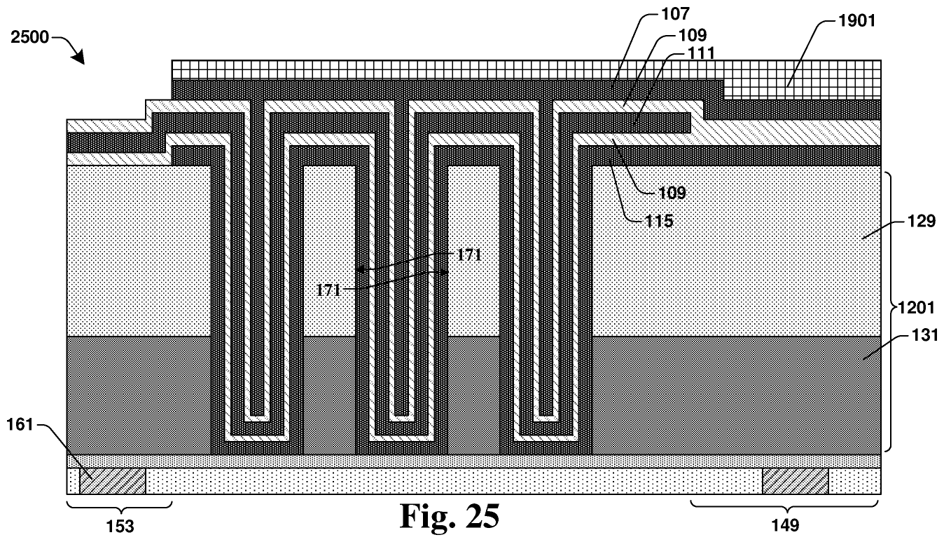

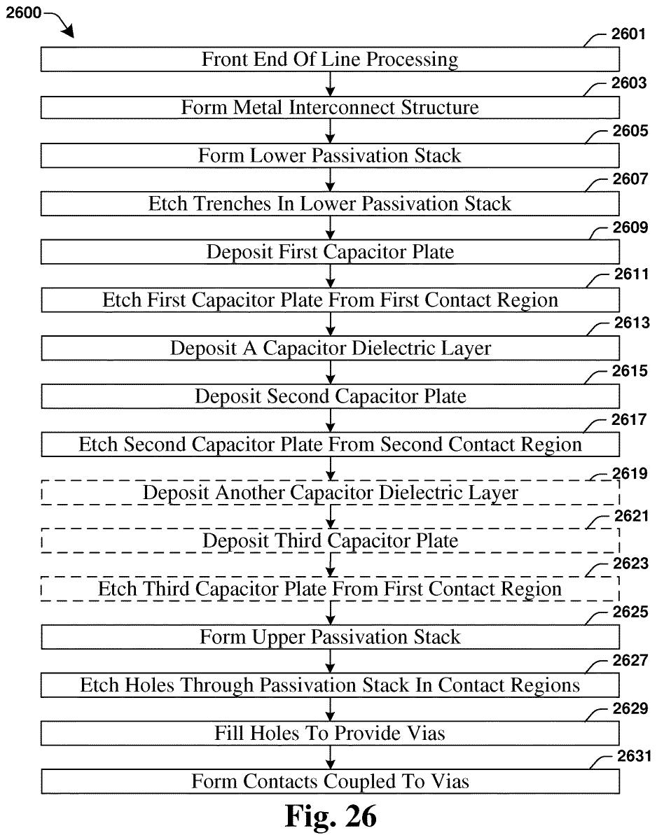

FIGS. 23-25 illustrate a variation of the foregoing process. As shown by the cross-sectional view 2300 of FIG. 23, the etch that removes the second plate 111 from the second contact region 149 may stop on the capacitor dielectric 109. As shown by the cross-sectional view 2400 of FIG. 24, a second layer of the capacitor dielectric 109 and the third plate 107 may then be formed over the structure shown by the cross-sectional view 2300 of FIG. 23. As shown by the cross-sectional view 2500 of FIG. 25, the etch that removes the third plate 107 from the first contact region 153 may also stop on the capacitor dielectric 109. Processing may continue as shown by the cross-sectional views 2000-2200 of FIGS. 20-22 to provide the IC device 300 shown in FIG. 3. Using etch processes that stop on the capacitor dielectric 109 may have advantages, such as preserving the integrity of the underlying capacitor plate.

FIG. 26 provides a flow diagram for a method 2600 of forming an IC device according to some embodiments. While the method 2600 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2600 begins with act 2601, front-end-of-line (FEOL) processing of a semiconductor substrate. FEOL processing forms semiconductor devices in or on the semiconductor substrate. These may include, for example, transistors, diodes, capacitors, memory cells, thyristors, resistors, the like, and combinations thereof. Act 2603 is back-end-of-line (BEOL) processing that provides a metal interconnect structure. The metal interconnect structure has wiring that connects the various semiconductor devices into functional circuits. Act 2605 is forming the lower portion of a passivation stack on the metal interconnect structure. The cross-sectional view 1200 of FIG. 12 provides an example.

Act 2607 is etching trenches in the lower portion of the passivation stack. The cross-sectional view 1300 of FIG. 13 provides an example. When the layers of a capacitor stack are deposited over and inside these trenches, they will form a trench capacitor structure.

Act 2609 is depositing the first capacitor plate. The cross-sectional view 1400 of FIG. 14 provides an example. Act 2611 is etching the first capacitor plate from the first contact region. The cross-sectional view 1500 of FIG. 15 provides an example.

Act 2613 is depositing a capacitor dielectric layer. In some embodiments, the capacitor dielectric layer has uniform thickness. In some embodiments, the capacitor dielectric is made to form more thickly where it extends horizontally over the passivation stack as compared to its thickness within the trenches. Act 2615 is depositing a second capacitor plate. The cross-sectional view 1600 of FIG. 16 provides an example.

Act 2617 is etching the second capacitor plate from the second contact region. The cross-sectional view 1700 of FIG. 17 provides an example in which the etch process stops on the first capacitor plate. The cross-sectional view 2300 of FIG. 23 provides an example in which the etch process stops on the capacitor dielectric.

Acts 2619 through 2623 are optional. Act 2619 is depositing an additional capacitor dielectric layer. Act 2621 is depositing an additional capacitor plate. The cross-sectional views 1800 and 2400 of FIGS. 18 and 24 provide examples.

Act 2623 is etching the additional capacitor plate from the first contact region. The cross-sectional view 1900 of FIG. 19 provides an example in which the etch process stops on the first capacitor plate. The cross-sectional view 2500 of FIG. 25 provides an example in which the etch process stops on the capacitor dielectric. Acts 2619 through 2623 may be repeated, with successive plates being etched from alternating contact regions.

Act 2625 is forming an upper portion of the passivation stack. The cross-sectional view 2000 of FIG. 20 provides an example. Act 2627 is etching holes or trenches through the passivation stack in the contact regions. The cross-sectional view 2100 of FIG. 21 provides an example. Act 2629 is filling the holes to create vias that contact the capacitor plates and connect with wires in the underlying metal interconnect structure. The cross-sectional view 2200 of FIG. 22 provides an example.

Act 2631 is forming contacts. The contacts are coupled to the vias and may be over the passivation stack. In some embodiments, the contacts are contact pads directly over the wires. In some embodiments, the contacts pads are etched from the metal deposited to form the vias. The cross-sectional view 2200 of FIG. 22 provides an example of how this etch may be accomplished. Alternatively, the vias may be connected to the contact pads by power rails over the passivation stack. The contacts are coupled to an external power source to activate the integrated circuit device.

Some aspects of the present disclosure relate to an integrated circuit (IC) device that includes a substrate, a metal interconnect structure over the substrate, and a passivation stack over the metal interconnect structure. The metal interconnect structure includes a first wire and a second wire. A first contact and a second contact are disposed over the passivation stack. A first via extending through the passivation stack connects the first contact to the first wire. A second via extending through the passivation stack connects the second contact to the second wire. A metal-insulator-metal capacitor having a trench capacitor structure is connected between the first via and the second via.

In some embodiments, the first via passes through and is surrounded by a first plate of the metal-insulator-metal capacitor and the second via passes through and is surrounded by a second plate of the metal-insulator-metal capacitor. In some embodiments, the trench capacitor structure extends below the first wire.

In some embodiments, the first contact and the second contact connect the IC device to a power supply. In some embodiments, the IC device has a third contact over the passivation stack and a third via disposed in the passivation stack and connected to the third contact, wherein the third via is connected to the metal-insulator-metal capacitor in parallel with the first via. In some embodiments, the first via and the second via are elongated so as to form vertical slabs. In some embodiments, the first via is one of a plurality of first vias that connect the first contact to the metal-insulator-metal capacitor. In some embodiments, the metal-insulator-metal capacitor is entirely within the passivation stack. In some embodiments, the passivation stack comprises a barrier layer, and the metal-insulator-metal capacitor extends into the barrier layer.

Some aspects of the present disclosure relate to an integrated circuit (IC) device that includes a semiconductor substrate, a metal interconnect structure over the semiconductor substrate, a dielectric structure over the metal interconnect structure, first and second contacts over the dielectric structure, and a capacitor comprising a first plate and a second plate separated by a capacitor dielectric layer. A first via passes through the dielectric structure and couples the first contact to the metal interconnect structure. A second via passes through the dielectric structure and couples the second contact to the metal interconnect structure. The first via passes through and contacts the first plate. The second via passes through and contacts the second plate. The first plate includes a first vertical portion disposed between a first two sidewalls of the dielectric structure. The second plate includes a second vertical portion disposed between the first two sidewalls of the dielectric structure.

In some embodiments, the first plate abuts and is over an etch stop layer. In some embodiments, the capacitor comprises a third plate, the second plate extends between the first plate and the third plate, and the first via passes through and contacts the third plate. In some embodiments, the first plate descends into one of the plurality of metallization layers. In some embodiments, the first plate includes a third vertical portion disposed between a second two sidewalls of the dielectric structure, wherein the second two sidewalls are laterally offset from the first two sidewalls and the second plate includes a fourth vertical portion disposed between the second two sidewalls of the dielectric structure. In some embodiments, the second two sidewalls are on an opposite side of the first via from the first two sidewalls. In some embodiments, the first plate includes a horizontal portion. the capacitor dielectric is disposed over the horizontal portion and between the first two sidewalls, and the capacitor dielectric is thicker above the horizontal portion than it is between the first two sidewalls.

Some aspects of the present disclosure relate method of forming an IC device, the method comprising providing a semiconductor substrate having a first contact region and a second contact region, forming a metal interconnect structure comprising a plurality of metallization layers over the semiconductor substrate, forming a first dielectric layer over the metal interconnect structure, forming a trench extending into the first dielectric layer, forming a first electrode metal layer over the first dielectric layer and within the trench, forming a first mask and etching to selectively remove the first electrode metal layer from the first contact region, forming a capacitor dielectric layer and a second electrode metal layer over the first electrode metal layer, forming a second mask and etching to selectively remove the second electrode metal layer from the second contact region, forming a second dielectric layer above the second electrode metal layer, etching holes, wherein the holes comprise a first hole in the first contact region and a second hole in the second contact region, wherein the first hole extends through the second dielectric layer, the second electrode metal layer, and the first dielectric layer, and the second hole extends through the second dielectric layer, the first electrode metal layer, and the first dielectric layer, and filling the holes with conductive material to form vias including a first via in the first hole and a second via in the second hole, wherein the first via contacts the second electrode metal layer and the second via contacts the first electrode metal layer.

In some embodiments, etching to selectively remove the first electrode metal layer from the first contact region leaves the first electrode metal layer surrounding the first contact region. In some embodiments, etching to selectively remove the second electrode metal layer from the second contact region is an etch process that stops on the capacitor dielectric layer. In some embodiments, forming the capacitor dielectric layer comprises a deposition process that causes the capacitor dielectric layer to be thinner within the trench than outside the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate;
metal interconnect structure over the substrate, wherein the metal interconnect structure comprises a first wire and a second wire;
a passivation stack over the metal interconnect structure;
a first contact and a second contact over the passivation stack;
a first via disposed in the passivation stack and connecting the first contact to the first wire;
a second via disposed in the passivation stack and connecting the second contact to the second wire; and
a metal-insulator-metal capacitor connected between the first via and the second via, wherein the metal-insulator-metal capacitor has a trench capacitor structure.

2. The IC device of claim 1, wherein the first via passes through and is surrounded by a first plate of the metal-insulator-metal capacitor and the second via passes through and is surrounded by a second plate of the metal-insulator-metal capacitor.

3. The IC device of claim 1, wherein the trench capacitor structure extends below the first wire.

4. The IC device of claim 1, wherein the first contact and the second contact connect the IC device to a power supply.

5. The IC device of claim 1, further comprising a third contact over the passivation stack and a third via disposed in the passivation stack and connected to the third contact, wherein the third via is connected to the metal-insulator-metal capacitor in parallel with the first via.

6. The IC device of claim 1, wherein the first via and the second via are elongated so as to form vertical slabs.

7. The IC device of claim 1, wherein the first via is one of a plurality of first vias that connect the first contact to the metal-insulator-metal capacitor.

8. The IC device of claim 1, wherein the metal-insulator-metal capacitor is entirely within the passivation stack.

9. The IC device of claim 1, wherein the passivation stack comprises a barrier layer, and the metal-insulator-metal capacitor extends into the barrier layer.

10. An integrated circuit (IC) device, comprising:
a semiconductor substrate;
a metal interconnect structure over the semiconductor substrate, wherein the metal interconnect structure comprises wires grouped into a plurality of metallization layers and vias grouped into a plurality of via layers, wherein the via layers are interleaved with the metallization layers;
a dielectric structure over the metal interconnect structure;
a first contact over the dielectric structure;
a first via passing through the dielectric structure and coupling the first contact to the metal interconnect structure;
a second contact over the dielectric structure;
a second via passing through the dielectric structure and coupling the second contact to the metal interconnect structure; and
a capacitor comprising a first plate and a second plate separated by a capacitor dielectric layer;
wherein the first via passes through and contacts the first plate;
the second via passes through and contacts the second plate;
the first plate includes a first vertical portion disposed between a first two sidewalls of the dielectric structure; and
the second plate includes a second vertical portion disposed between the first two sidewalls of the dielectric structure.

11. The IC device of claim 10, wherein the first plate abuts and is over an etch stop layer.

12. The IC device of claim 10, wherein the capacitor comprises a third plate, the second plate extends between the first plate and the third plate, and the first via passes through and contacts the third plate.

13. The IC device of claim 10, wherein the first plate descends into one of the plurality of metallization layers.

14. The IC device of claim 10, wherein:
the first plate includes a third vertical portion disposed between a second two sidewalls of the dielectric structure, wherein the second two sidewalls are laterally offset from the first two sidewalls; and
the second plate includes a fourth vertical portion disposed between the second two sidewalls of the dielectric structure.

15. The IC device of claim 14, wherein the second two sidewalls are on an opposite side of the first via from the first two sidewalls.

16. The IC device of claim 10, wherein;
the first plate includes a horizontal portion;
the capacitor dielectric is disposed over the horizontal portion and between the first two sidewalls; and
the capacitor dielectric is thicker above the horizontal portion than it is between the first two sidewalls.

17. A method of forming an integrated circuit (IC) device, the method comprising:
providing a semiconductor substrate having a first contact region and a second contact region;
forming a metal interconnect structure comprising a plurality of metallization layers over the semiconductor substrate;
forming a first dielectric layer over the metal interconnect structure;
forming a trench extending into the first dielectric layer;
forming a first electrode metal layer over the first dielectric layer and within the trench;
forming a first mask and etching to selectively remove the first electrode metal layer from the first contact region;
forming a capacitor dielectric layer and a second electrode metal layer over the first electrode metal layer;
forming a second mask and etching to selectively remove the second electrode metal layer from the second contact region;
forming a second dielectric layer above the second electrode metal layer;
etching holes, wherein the holes comprise a first hole in the first contact region and a second hole in the second contact region, wherein the first hole extends through the second dielectric layer, the second electrode metal layer, and the first dielectric layer, and the second hole extends through the second dielectric layer, the first electrode metal layer, and the first dielectric layer; and
filling the holes with conductive material to form vias including a first via in the first hole and a second via in the second hole, wherein the first via contacts the second electrode metal layer and the second via contacts the first electrode metal layer.

18. The method of claim 17, wherein etching to selectively remove the first electrode metal layer from the first contact region leaves the first electrode metal layer surrounding the first contact region.

19. The method of claim 17, wherein etching to selectively remove the second electrode metal layer from the second contact region is an etch process that stops on the capacitor dielectric layer.

20. The method of claim 17, wherein forming the capacitor dielectric layer comprises a deposition process that causes the capacitor dielectric layer to be thinner within the trench than outside the trench.
